(19) United States
(12) Patent Application Publication
(10) Pub. No.: US 2004/0193974 A1
(43) Pub. Date: Sep. 30, 2004

(54) Systems and methods for voice quality testing in a packet-switched network

(76) Inventors: James P. Quan, Colorado Springs, CO (US); Samuel M. Bauer, Colorado Springs, CO (US)

Correspondence Address: AGILENT TECHNOLOGIES, INC., Legal Department , DL429, Intellectual Property Administration, P.O. Box 7599, Loveland, CO, 80537-0599, US

(21) Appl. No.: 10/400,229

(22) Filed: Mar. 26, 2003

(51) Int. Cl. G01R 31/28; H03M 13/00

(52) U.S. Cl. 714/724

(57) ABSTRACT

A system and method for voice quality testing (VQT) in a packet switched voice communications network. A test system comprises a set of pre-encoded test data. The test data is pre-encoded using a set of audio codecs that can be used for voice communication on the network. During VQT, data can be selected from the set of pre-encoded data for transmission over the network, thereby eliminating the real-time overhead involved in voice coding of the test audio waveforms. The pre-encoding can also be extended to include processing associated with one or more data transmission protocols, thus further reducing the computational requirements for testing. To reduce the size of the set of test data, codecs on the network can be identified and test data pre-encoded using only the identified codecs prior to VQT.

### BACKGROUND

Traditionally, digital voice communication has relied primarily on circuit-switched networks such as the T-carrier system. However, packet-switched networks (e.g. the Internet) are being increasingly used for voice communications. The adoption of packet-switched networks for voice communication has engendered a requirement for testing the capability of a packet-switched network for handling the unique requirements of voice transmission, that is, voice quality testing (VQT).

FIG. 1 shows an example of a protocol stack 100 that can be used for packet switched voice communications such as Voice over Internet Protocol (VoIP). The protocol stack is mapped onto the Open Systems Interconnect (OSI) model. The applications layer 105 includes the analog audio signal generation and handling. Conventional VQT functionality, if present, would reside in the applications layer 105.

The presentation layer 110 includes audio codecs that can be used for voice coding (vocoding). Such codecs can include G.711, G.722, G.723.1, G.729, and their variants. The presentation layer can provide formatting, code conversion, compression, and encryption.

The session layer 120 can include the Real-Time Transport Protocol (RTP), which provides the first stage of packetization of the coded voice. RTP provides support for applications with real-time properties, including timing reconstruction, loss detection, security and content identification. In general, the session layer provides for the setup and maintenance of connections to a process between two different users (call channels).

The transport layer 130 can include the User Datagram Protocol (UDP), or Transmission Control Protocol (TCP). This layer handles the second stage of packetization. The transport layer handles error recovery and flow control between endpoints on the network.

The network layer 140, data link layer 150, and physical layer 160 are concerned with the internal functions of the packet-switched network. The network layer 140 can include the Internet Protocol (IP), and the data link layer can include the IEEE 802 (e.g. 802.2 and 802.3) logical link control (LLC) layer and media access control (MAC) layer. The network and data link layers provide framing and other services for node-to-node transfer within the packet-switched network. The physical layer provides the interface to the physical medium over which the data is sent.

The different layers of the protocol stack of FIG. 2 can be executed on various combinations of hardware and software. For example, layers 105, 110, 120, 130, and 140 can be executed in software by a general purpose microprocessor, with layers 150 and 160 executed by dedicated hardware and firmware coupled to the general purpose microprocessor by a bus. Alternatively, a digital signal processor (DSP) can also be used for execution of codecs associated with layer 110.

Comprehensive VQT in a packet network requires significant computational power for voice encoding, multiple call channel generation, and test signal evaluation. Accordingly, methods for reducing computational demands without reducing test efficacy are sought.

### SUMMARY

Embodiments of the present invention pertain to systems and methods for voice quality testing. Audio waveforms used for testing are pre-encoded using a variety of codecs to produce a set of test data that can be transmitted over a network. The pre-encoding of the audio waveforms reduces the real-time requirement for computation during testing.

Systems and methods for voice quality testing (VQT) in a packet switched voice communications network are disclosed. In one embodiment, a test system comprises a set of pre-encoded test data. The test data is pre-encoded using a set of audio codecs that can be used for voice communication on the network. During VQT, data can be selected from the set of pre-encoded data for transmission over the network, thereby eliminating the real-time overhead involved in voice coding of the test audio waveforms. The pre-encoding can also be extended to include processing associated with one or more data transmission protocols, thus further reducing the computational requirements for testing. To reduce the size of the set of test data, codecs on the network can be identified and test data pre-encoded using only the identified codecs prior to VQT.

In one embodiment, a test system comprises a set of pre-encoded audio data coupled to a test controller. The test controller has one or more interfaces for coupling to a network. Each of the interfaces can be related to a data transmission protocol. The test system can also comprise a detector for determining the presence and type of audio codecs and data transmission protocols present on the network. The test system can also comprise a pre-encoder and a set of audio data for producing a set of pre-encoded data using codecs or data transmission protocols detected by the detector.

In another embodiment, a method for VQT is provided. Analog waveforms for VQT in a network are digitized and pre-encoded to produce test data. The pre-encoding can comprise processing of the digitized waveforms using a set of audio codecs. Data can be selected from the set of test data and transmitted over the network. Transmitted data can be received over the network and characterized.

### BRIEF DESCRIPTION OF THE DRAWINGS

The accompanying drawings, which are incorporated in and form a part of this specification, illustrate embodiments of the invention and, together with the description, serve to explain the principles of the invention. The drawings referred to in this description should not be understood as being drawn to scale except if specifically noted.

FIG. 1 shows a conventional protocol stack used for voice quality testing in a communications network, mapped onto the Open Systems Interconnect (OSI) model.

FIG. 2 is block diagram of an end-to-end voice communication system with a test configuration in accordance with an embodiment of the present invention.

FIG. 3 shows embodiments of the present invention mapped onto the Open Systems Interconnect (OSI) model.

FIG. 4 shows a functional block diagram for a pre-encoded test file voice quality testing (VQT) system, in accordance with an embodiment of the present invention.

FIG. 5 shows a flow diagram for a method for voice quality testing (VQT) in a packet-switched network voice communications system in accordance with an embodiment of the present invention.

### DETAILED DESCRIPTION OF THE INVENTION

### Terminology and Overview

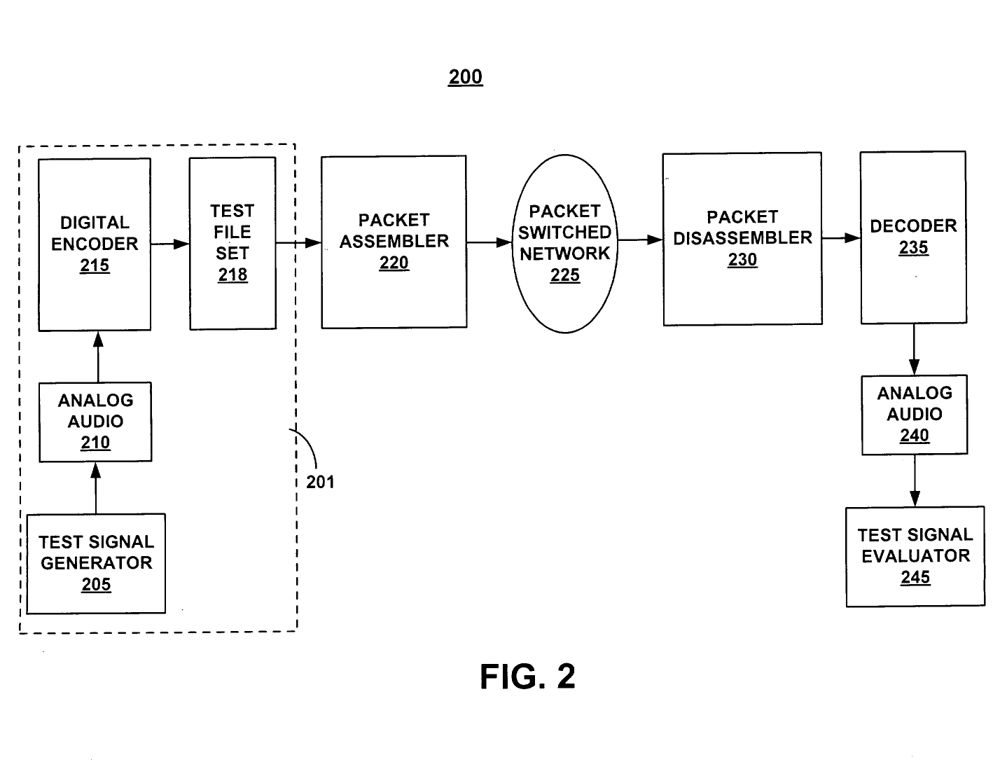

FIG. 2 shows a functional block diagram 200 for a representative voice communication system and test setup in accordance with an embodiment of the present invention. The system comprises the general elements of a test signal generator 205 for producing an analog input signal 210, a digital encoder 215, a test file set 218, a packet assembler 220, a packet-switched network 225, a packet disassembler 230, a decoder 235 producing an output analog signal 240, and a test signal evaluator 245.

The test signal generator 205 produces an acoustic or electronic analog signal (e.g., voice, or voice equivalent) 210 that is applied to the digital encoder 215. Digital encoding includes the analog-to-digital conversion of the analog signal 210, and can also include compression, encryption, and other digital signal processing, such as the application of an audio codec. Although pre-encoding of voice is described as a specific example, it should be noted that embodiments of the present invention can also include the pre-encoding of other audio material such as music or environmental sounds.

Because of its redundant nature, human speech lends itself well to compression, and compression is a desirable way to increase information transfer. However, compression increases the sensitivity of the information stream to corruption. Thus, there is an unavoidable tradeoff between data transfer rate and quality.

In voice communication, it has been a common practice to limit sampling rates and the sample resolution in order to reduce the demands on the transmission network. For example, the ITU-T standard G.711 specifies an 8 kHz sampling rate and an 8-bit sample, producing a 64 kbps data stream. The 8 kHz sampling rate effectively restricts the system analog frequency response to less than 4 kHz, although the human auditory range extends to about 20 kHz. Typically, voice coding (vocoding) is a lossy process that sacrifices a finite amount of signal quality in order to increase overall information flow in a network.

The use of lossy compression has led to the development of sophisticated vocoders (voice coders) in order to achieve the maximum reduction in data rates while minimizing loss of quality. Voice communication places a unique demand on a digital network in that it is difficult to correlate bit loss/corruption with the ultimate perception by a human of the transmitted signal. This lack of correlation leads to vocoding algorithms that are computationally intensive. For example, anywhere from 10-20 million instructions per second (MIPs) can be required to support a voice call channel on a packet network using standard voice encoding schemes.

The digital information sequence produced by the digital encoder 215 is stored in a test file set 218. The test file set 218 may be stored in a volatile or non-volatile memory medium. The pre-encoded test file set 218 allows Block 201 to be temporally decoupled from the processes of the remainder of the network, thus reducing competition for processing resources during data transmission in the system. During testing, the data required for testing is extracted from the pre-encoded test file set 218.

The information stored in the test file set 218 is passed to a packet assembler 220 that converts the information to a series of packets for transmission over the packet-switched network 225. The packet-switched network 225 transports the packets produced by the packet assembler 220 to a packet disassembler 230. In addition to being affected by environmental influences (e.g. electrical noise), a packet-switched network is also subject to packet loss that arises through delays due to network congestion. Thus, for testing purposes, it is desirable to setup simultaneous call channels in order to stress the network. The maintenance of multiple calls increases the computational demands on the test system.

The packet disassembler 230 receives the packets from the packet-switched network 225 and extracts the digital information sequence that was input to the packet assembler 220. The recovered digital sequence is passed to a decoder 235 that produces an output analog signal 240. The output analog signal is passed to a test signal evaluator 245.

The test signal evaluator 245 compares the output signal 240 to the input signal 210. In evaluation, the differences between the input and output signal are determined. As stated above, there is usually a certain amount of intentional loss of quality involved in the encoding process, and there are additional losses and/or distortion that are involved in the transmission over the network. In general, there are a number of factors involved in determining voice quality. Among these factors are delay, echo, and clarity.

Although delay and echo are relatively easy to quantify and understand, clarity is considerably more difficult to quantify. Historically, clarity has been measured using the mean opinion score (MOS), derived from a group of live listeners. With reference to FIG. 2, the test signal evaluator 245 would be the group of listeners, and the analog audio would be an acoustic signal. More recently, computer-based methods have been developed to produce objective measurements of perceived voice quality. The computational demands of evaluating decoded voice transmissions are similar to those of encoding voice, in that human perception must be taken into account.

Two examples of clarity measurement techniques are the Perceptual Speech Quality Measurement (PSQM) method, and the Perceptual Analysis/Measurement System (PAMS) method. Recently, the Perceptual Evaluation of Speech Quality (PESQ) model has been introduced, combining elements of both PSQM and PAMS. Referring again to FIG. 2, the analog audio signal 240 can be bypassed, and the decoder output passed directly to a computer 245 for evaluation of a partially decoded signal that is still digitized.

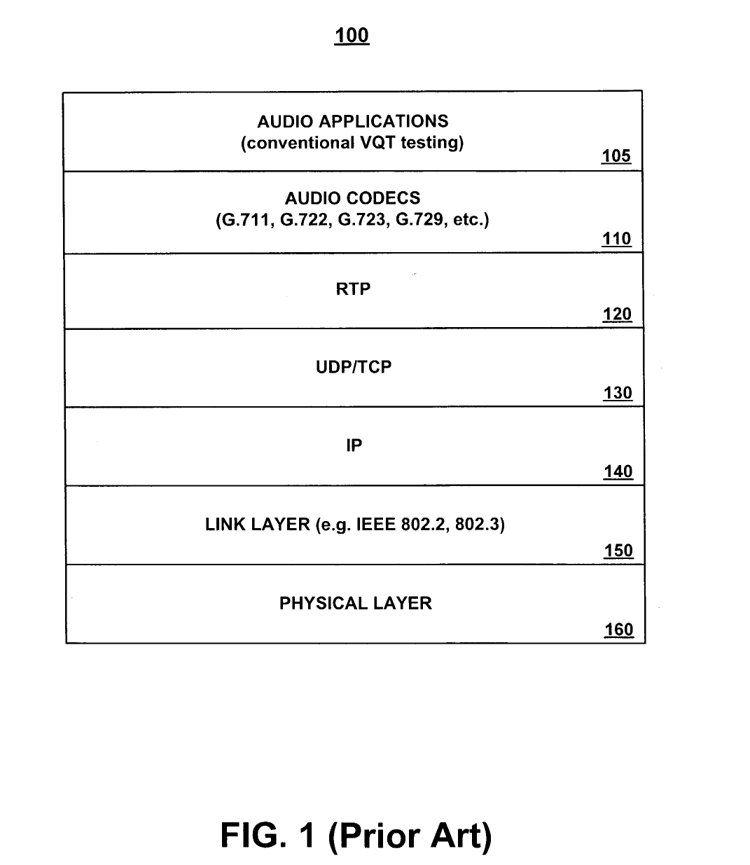

Voice quality testing (VQT) is generally a real-time process, with each layer of the protocol stack 100 of FIG. 1 contributing to the overall computational overhead. In embodiments of the present invention, test data is pre-encoded for delivery to layers below the presentation (codec) layer 110 of FIG. 1 . In this way, the computational demands and potential bottlenecks of the upper layer protocols can be eliminated.

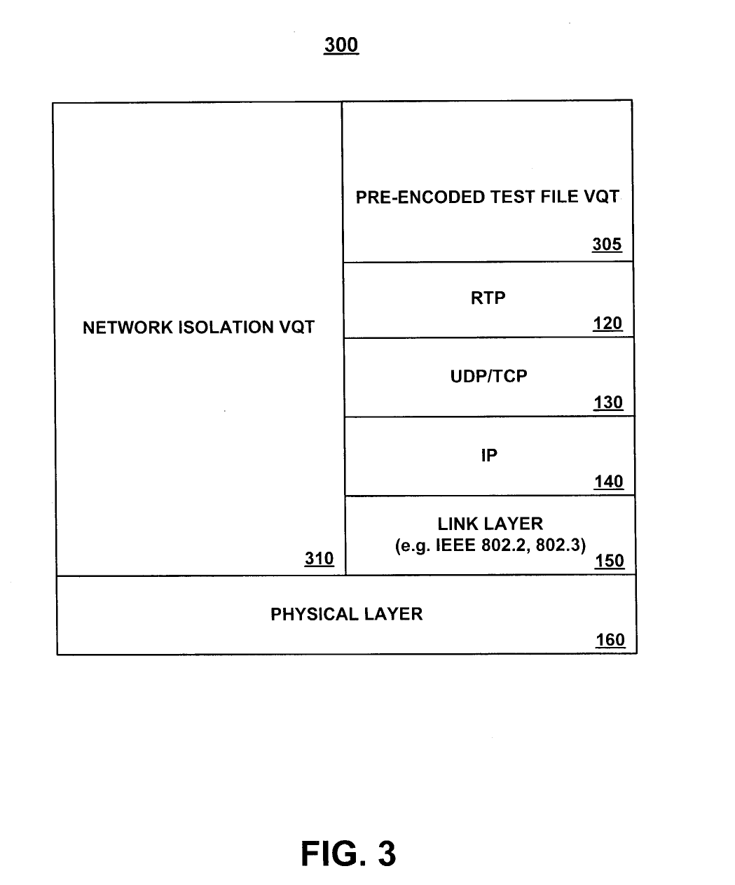

FIG. 3 shows a diagram 300 of embodiments of the present invention mapped onto the Open Systems Interconnect (OSI). In contrast to testing a packet switched communications network by exercising the functionality of the layers 110 through 160 by executing an application that resides above layer 110 as shown in FIG. 1, embodiments of the present invention use pre-encoded data that is passed to layers below layer 110, thereby reducing the computational overhead associated with layer 110. In one embodiment, a test application 305 passes data directly to the session layer 120.

In an alternative embodiment, a network isolation VQT application 310 bypasses layers 110, 120, 130, 140, and 150, passing data packets directly to the physical layer 160. Although the greatest amount of processing resources is typically required by the audio codecs associated with the presentation layer 110, other layers of the protocol stack can have processes that do not require real-time processing. These processes can be pre-encoded to further reduce processor loading. Application 310 may be used to provide background traffic to stress a packet-switched network. This traffic can include packets that carry information that is not analyzed during testing.

### Pre-encoded Test File System for VQT

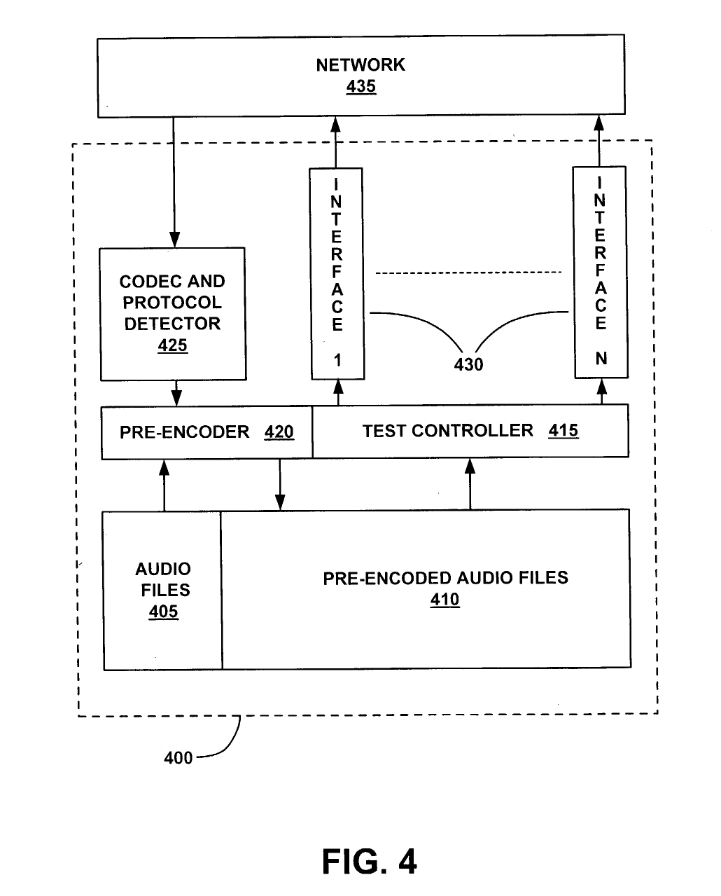

FIG. 4 shows one embodiment of a VQT system 400 coupled to a network 435. The embodiment of FIG. 4 includes a number of functional blocks that are separately illustrated and described. However, it is appreciated that a block—and its functionality—can be combined with another block. It is also appreciated that system 400 can include other elements not shown or described. In general, system 400 provides for the introduction of pre-encoded audio files to a network for VQT.

In one embodiment the system comprises a storage medium 410 for pre-encoded data coupled to a test controller 415. The pre-encoded data comprises audio waveforms (e.g. voice) that have been digitized and encoded. Encoding can include compression, encryption, filtering, or other processing. Pre-encoding can include the data processing functions that are part of various data transmission protocols such as RTP (session layer), UDP (transport layer), IP (network layer), and Ethernet (data link layer). Pre-encoding may also include the addition of formatting information used for accessing the contents of the file.

Examples of codecs that can be used for pre-encoding are ITU-T standards G.711, G.723.1, G.726, G.728, and G.729. The bit rates required by these codecs ranges from about 5kbps to 64kbps. In general, more computational power is required to achieve a lower bit rate while minimizing loss of quality. Codecs such as G.729 and G.723.1 have a voice activity detector (VAD) feature that allows the packet transmissions to be reduced during periods of silence. During periods of silence, a comfort noise generator (CNG) can be used to provide a background noise. These features can be accommodated during pre-encoding.

In order to limit the size of the set of pre-encoded files 410, the test system 400 optionally includes storage 405 for a set of unencoded audio files (e.g., wave files), a pre-encoder 420, and a codec and protocol detector 425. The detector 425 is coupled to the network 435 and determines the audio codecs and data transmission protocols in use on the network 435. This information is passed to the pre-encoder 420, so that unencoded audio files can be pre-encoded to produce the necessary set of test files on a storage medium 410. In this way, the test file set can be limited to only those files necessary for a specific test instance.

A set of test files pre-encoded just prior to test after detection of a codec or protocol can be referred to as a dynamic test file library, and can be stored in a volatile memory, or on an optical or magnetic storage medium such as a disk drive. A set of files that is encoded and made available for a series of tests is referred to as a static test file library, and is typically stored on an optical or magnetic storage medium such as disk drive. In general the unencoded audio files 410 and pre-encoded files 410 are referred to as a test data source.

In the embodiment of FIG. 4, test controller 415 handles the overall test flow/script and submits the test files 410 to the network. Audio codecs typically produce a series of frames as an output. During test file encoding, the framing may be altered by data formatting within the file. The test controller 415 can unpack a data file and restore a series of frames as necessary. The controller 415 is coupled to the network by one or more interfaces 430. Each of the N interfaces 430 conforms to a particular data transmission protocol, and allows files with different levels of pre-encoding to be introduced to the network. The interfaces can be software interfaces, or they can include interfaces specified at the physical layer. For example, the test system 400 may be plugged directly into an Ethernet port.

For network hardware that relies on a single processor handling more than one layer of the media/protocol stack, pre-encoding reduces the loading of the processor and enables the system being tested to achieve a higher throughput. The higher throughput can be used to achieve a background traffic level for stress testing of the network. For example, several simultaneous VoIP call channels can be set up, with VQT being performed on one call channel or a subset of the call channels being maintained. By changing the total number of channels being maintained, the voice quality effects due to network capacity can be evaluated.

### Method for Enhanced VQT

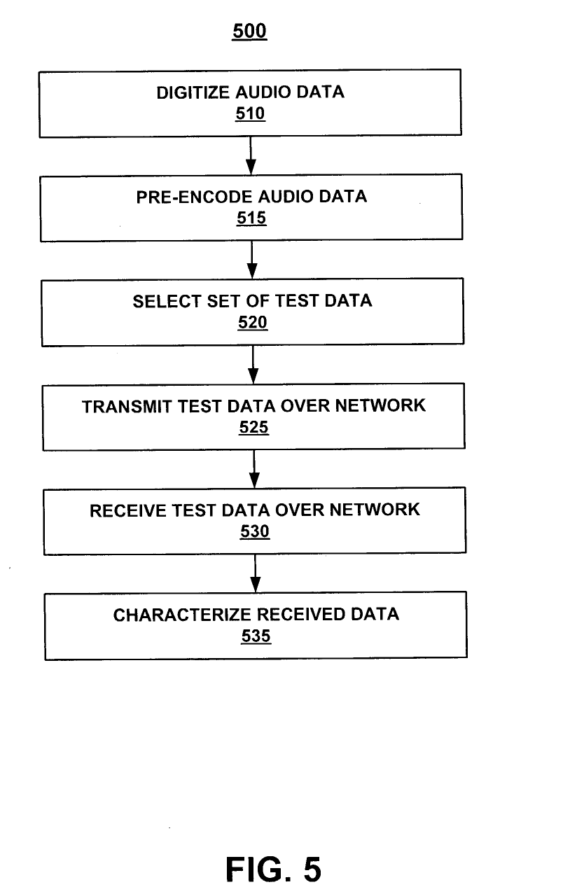

FIG. 5 is a flowchart 500 of a method embodiment for VQT. Although specific steps are disclosed in flowchart 500, such steps are exemplary. In step 510, audio data, such as speech is digitized to produce a set of unencoded digital audio data files. The data files can be synthesized, or can be produced by analog-to-digital conversion of acoustic waveforms. The audio data files can or can not be stored in a test system.

In step 515, the audio data files are pre-encoded to produce a set of pre-encoded test files. Pre-encoding can be done using a variety of audio codecs, and is preferably done using widely used codecs, and codecs that are known to be processor intensive. Pre-encoding can be done to produce a dynamic library that is used for a specific test instance and includes only the files required the test, or it can be done to produce a static library from which files are selected for each test.

In step 520, test files are selected for transmission over the network. The set of files selected can be the entire set of files if a dynamic library is being used, or it can be a subset of a static library. In one embodiment, files can be selected from a static library to provide network background VQT stress, while a dynamic library is used simultaneously to provide files for VQT evaluation.

In step 525, the test files are transmitted over the network. Depending upon the degree of pre-encoding in the test files and the network architecture, the test files can be submitted to one of several available layers in the network being tested. During a test, more than one network layer can serve as the entry point for test file transmission.

In step 530, the test files are received over the network. In receiving the test files, files that were transmitted to produce network stress can be ignored, with the remaining files being passed on for characterization. File identification for characterization can be incorporated in packet headers associated with various data transmission protocols.

In step 535, the received data is characterized. Characterization typically include the extraction of the received test file and its evaluation with respect to file that was transmitted. Characterization can also include the generation of packet transmission data (e.g., high resolution time stamps) in addition to that provided by the data transmission protocols in use.

Various embodiments of the present invention are thus described. While the present invention has been described in particular embodiments, it should be appreciated that the present invention should not be construed as limited by such embodiments, but rather construed according to the following claims.

What is claimed is:

1. A system for voice quality testing of a voice communications network comprising:
a first storage medium for a set of pre-encoded test files;
a test controller coupled to said set of pre-encoded files; and
at least one interface coupled to said test controller for coupling said system to said network.

2. The system of claim 1, wherein said set of pre-encoded test files is pre-encoded using an audio codec.

3. The system of claim 2, wherein said audio codec is selected from the set consisting of ITU-T standards G.711, G.723.1, G.726, G.728, and G.729.

4. The system of claim 1, wherein said first storage medium comprises a dynamic test file library.

5. The system of claim 1, wherein said first storage medium comprises a static test file library.

6. The system of claim 1, further comprising a second storage medium for storing a set of unencoded audio files.

7. The system of claim 6, further comprising a pre-encoder coupled to said second storage medium.

8. The system of claim 7, further comprising a detector coupled to said pre-encoder for determining a codec or a protocol on said network.

9. The system of claim 1, wherein said interface is for coupling to a physical layer of said network.

10. The system of claim 1, wherein said first storage medium comprises test files pre-encoded using processing associated with one or more data transmission protocols.

11. A method for voice quality testing for a packet-switched voice communications network comprising:
transmitting one or more pre-encoded audio files over said network;
receiving one or more of said pre-encoded audio files over the network; and
characterizing one or more of said pre-encoded audio files.

12. The method of claim 11, further comprising synthesizing said audio files.

13. The method of claim 12, further comprising performing an analog-to-digital conversion of an acoustic waveform to produce said audio files.

14. The method of claim 11, wherein said pre-encoding comprises using processing associated with one or more data transmission protocols.

15. The method of claim 14, wherein said pre-encoding comprises processing associated with Real-Time Transport Protocol (RTP).

16. The method of claim 14, wherein said pre-encoding comprises processing associated with User Datagram Protocol (UDP).

17. The method of claim 14, wherein said pre-encoding comprises processing associated with Internet Protocol (IP).

18. The method of claim 11, wherein said transmitting one or more pre-encoded audio files over the network comprises using an interface to a physical layer of the network.

19. The method of claim 11, wherein said transmitting one or more test files comprises transmitting all of said pre-encoded audio files.

20. The method of claim 19, further comprising detecting an audio codec or a protocol on the network.

21. A test data source for voice quality testing of a packet-switched network comprising:
a pre-encoded test file library comprising a plurality of pre-encoded audio files; and
a plurality of uncompressed audio files.

22. The test data source of claim 21, wherein said pre-encoded audio files are pre-encoded using an audio codec selected from the set consisting of ITU-T standards G.711, G.723.1, G.726, G.728, and G.729.

23. The test data source of claim 21, wherein said library comprises at least one file that is pre-encoded using an audio codec detected on a packet-switched network.

24. The test data source of claim 21, wherein said library comprises a dynamic test file library.

25. The test data source of claim 21, wherein said library comprises a static test file library.

26. A method for voice quality test of a packet-switched network using a voice quality testing system, said method comprising:
coupling said voice quality testing system to said packet-switched network;
transmitting a pre-encoded test file comprising audio data over said packet switched network;
receiving said pre-encoded test file over said packet-switched network; and
evaluating said pre-encoded test file.

27. The method of claim 26, further comprising transmitting a pre-encoded file for providing background traffic on said packet-switched network.

28. The method of claim 26, further comprising:
detecting an audio codec on said packet-switched network;
pre-encoding said test file using the detected audio codec.

29. The method of claim 26, further comprising selecting said pre-encoded test file from a static test file library.

30. The method of claim 26, wherein said voice quality testing system is coupled to said network using an Ethernet port.
